(19) United States
(12) Patent Application Publication
(10) Pub. No.: US 2006/0186398 A1
(43) Pub. Date: Aug. 24, 2006

(54) Organic semiconductor device with multiple protective layers and the method of making the same

(76) Inventors: Cheng-Chung Hsieh, Hsinchu (TW); Tarng-Shiang Hu, Hsinchu (TW); Jia-Chong Ho, Hsinchu (TW); Cheng-Chung Lee, Hsinchu (TW)

Correspondence Address: HARNESS, DICKEY & PIERCE, P.L.C., P.O. BOX 8910, RESTON, VA, 20195, US

(21) Appl. No.: 11/165,346

(22) Filed: Jun. 24, 2005

(30) Foreign Application Priority Data
Feb. 18, 2005 (TW) 94104890

(51) Int. Cl. H01L 29/08

(52) U.S. Cl. 257/40

(57) ABSTRACT

An organic semiconductor device with multiple protective layers and the method of making the same are described. A first protective layer is formed by vapor phase deposition on an organic thin-film transistor. A second protective layer is then formed on the first protective layer. Therefore, the organic thin-film transistor is formed with multiple protective layers. Not only do these protective layers have good homogeneity, they can protect the organic thin-film transistor from damages, ensuring good quality.

### BACKGROUND OF THE INVENTION

1. Field of Invention

The invention relates to an organic semiconductor device and the method of making the same. In particular, the invention relates to an organic semiconductor device with multiple protective layers and the method of making the same.

2. Related Art

Organic semiconductor devices have been a hot topic in the field. Take the organic thin-film transistor (OTFT) as an example. It has gradually been commercialized. Products that utilize the OTFT, such as the radio-frequency identification (RFID), have been in the phase of test mass production. In the future, the OTFT can be further used in flexible substrates, displays, and electronic paper. In particular, the OTFT has the advantages of easy production, low production temperature, and low cost. As long as the device lifetime can be greatly extended, their business potential will be unlimited.

However, the organic protective layers of the OTFT may encounter the problem of inhomogeneity if the coating is performed using purely the solution processes. In that case, the panel quality in the subsequent procedure is hard to maintain.

In the prior art, IBM Inc. proposed a method of making a protective layer of the pentacene OTFT by vapor phase deposition of an organic molecule, parylene. However, the parylene thin film is not compact, it cannot fully protect the pentacene OTFT and is susceptible to the liquid crystal. Moreover, the parylene molecule does not have sufficient side links for performing the required liquid crystal rubbing. Thus, the protective layers of an organic semiconductor device with the above-mentioned OTFT have many difficulties to be solved.

### SUMMARY OF THE INVENTION

In view of the foregoing, an object of the invention is to provide an organic semiconductor device with multiple protective layers and the method of making the same. By forming multiple protective layers on the OTFT, a flatter organic semiconductor device with good protective effects can be built, solving most of the problems in the prior art.

To achieve the above object, the disclosed organic semiconductor device with multiple layers is comprised of an OTFT, a first protective layer and a second protective layer. The first protective layer is formed by vapor phase deposition on the OTFT. The second protective layer is then formed on the first protective layer. Accordingly, the surface of the organic semiconductor device is more uniform, effectively protecting the OTFT.

Moreover, the method of making the organic semiconductor device with multiple protective layers includes the steps of: providing an OTFT; forming by vapor phase deposition a first protective layer on the OTFT; and forming a second protective layer on the first protective layer. This renders an organic semiconductor device with multiple protective layers.

In particular, the second protective layer can be formed in a solution process or by the same vapor phase deposition as the first protective layer, but with a different material. The first and second protective layers can be either inorganic or organic. Alternatively, one may form a plurality of organic first protective layers and a plurality of inorganic second protective layers in an alternating way on the OTFT. This will render an even more uniform and protective layer.

### BRIEF DESCRIPTION OF THE DRAWINGS

The invention will become more fully understood from the detailed description given hereinbelow illustration only, and thus are not limitative of the present invention, and wherein:

FIG. 1 is a flowchart of the disclosed method of making an organic semiconductor device with multiple protective layers;

FIGS. 2A to 2C show the cross sections of making the organic semiconductor device with multiple protective layers according to the invention;

FIGS. 3A to 3C show the I_{D}-V_{D} characteristic curves of the organic semiconductor device dropped with TNLC on the channel of the OTFT before and after the procedure in the first embodiment;

FIGS. 4A to 4C show the I_{D}-V_{G} characteristic curves of the organic semiconductor device dropped with TNLC on the channel of the OTFT before and after the procedure in the first embodiment; and

FIGS. 5A to 5D show the I_{D}-V_{D} characteristic curves of the organic semiconductor device dropped with TNLC and liquid crystal on the channel of the OTFT before and after the procedure and five days after the procedure in the second embodiment.

### DETAILED DESCRIPTION OF THE INVENTION

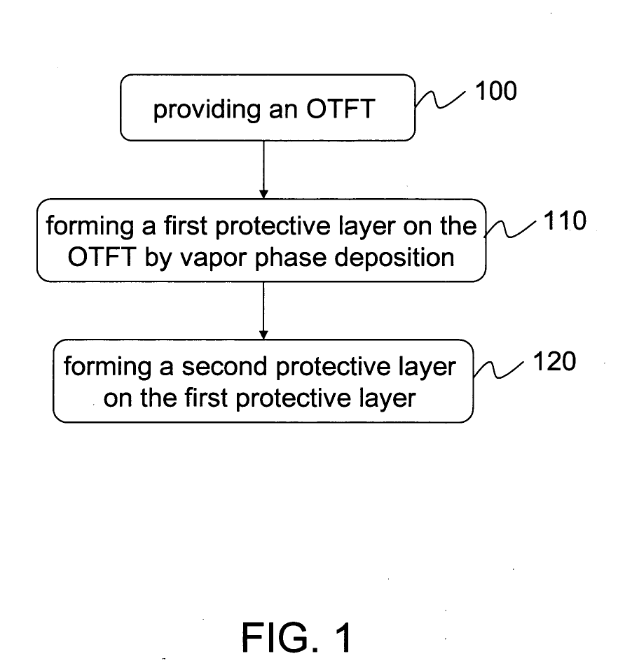

With reference to FIG. 1, the disclosed method of making an organic semiconductor device with multiple protective layers includes the following steps. First, an OTFT is provided (step 100). A first protective layer is formed by vapor phase deposition on the OTFT (step 110). Finally, a second protective layer is formed on the first protective layer by vapor phase deposition or a solution process (step 120) to cover the pinholes on the surface of the first protective layer and to increase the uniformity of the thin film. This achieves the goal of protecting the OTFT using multiple protective layers.

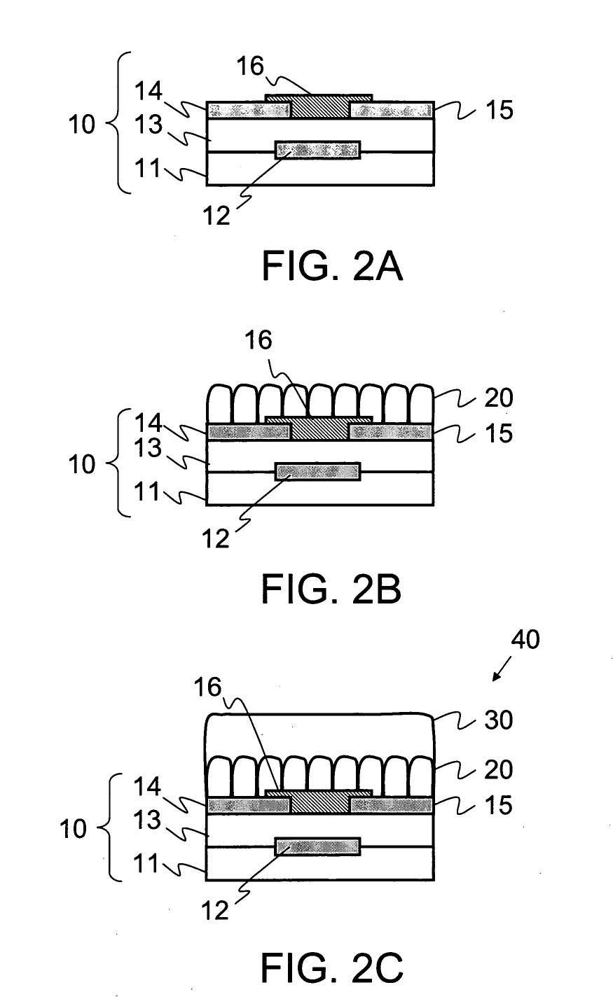

In the following, we use two embodiments to explain and verify the feasibility of the disclosed organic semiconductor device with multiple protective layers and the method of making the same. FIGS. 2A to 2C show the steps of the invention.

As shown in FIG. 2A, a contact pentacene OTFT 10 is provided (step 100). The OTFT 10 is constructed by forming in sequence on a substrate 11 a gate 12, an insulator 13, a source 14, a drain 15, and a pentacene organic semiconductor layer 16.

As shown in FIG. 2B, parylene powders are placed inside a vapor phase deposition device. They are heated to sublimate into gaseous molecules, which then break into smaller molecules at high temperatures. A parylene first protective layer 20 is formed on the OTFT 10 whose electrical properties have been verified. The parylenes include parylene-N, parylene-C, and parylene-D. In this embodiment, we use parylene-D to make the first protective layer 20. We use polymer deposition as the manufacturing process for the first protective layer 20.

As shown in FIG. 2C, when the electrical properties of the device is back to its original standard, a poly vinyl phenol (PVP) second protective layer 30 is formed on the first protective layer 20 in a solution process (step 120). It covers the pinholes on the surface of the first protective layer 20. This completes the manufacturing of the disclosed organic semiconductor device 40 with multiple protective layers.

The organic semiconductor device 40 with multiple protective layers provided in the first embodiment is comprised of an OTFT 10, a first protective layer 20, and a second protective layer 30, as shown in FIG. 2C. This OTFT 10 contains a substrate 11 along with a gate 12, an insulator 13, a source 14, a drain 15, and a pentacene organic semiconductor layer 16 formed in sequence on the substrate 11. The first protective layer 20 is formed by vapor phase deposition on the OTFT 10. The second protective layer 30 is formed on the first protective layer 20 to increase the protective effect and uniformity of the protective layer. The OTFT 10 is thus prevented from damages, ensuring the performance of the organic semiconductor device 40.

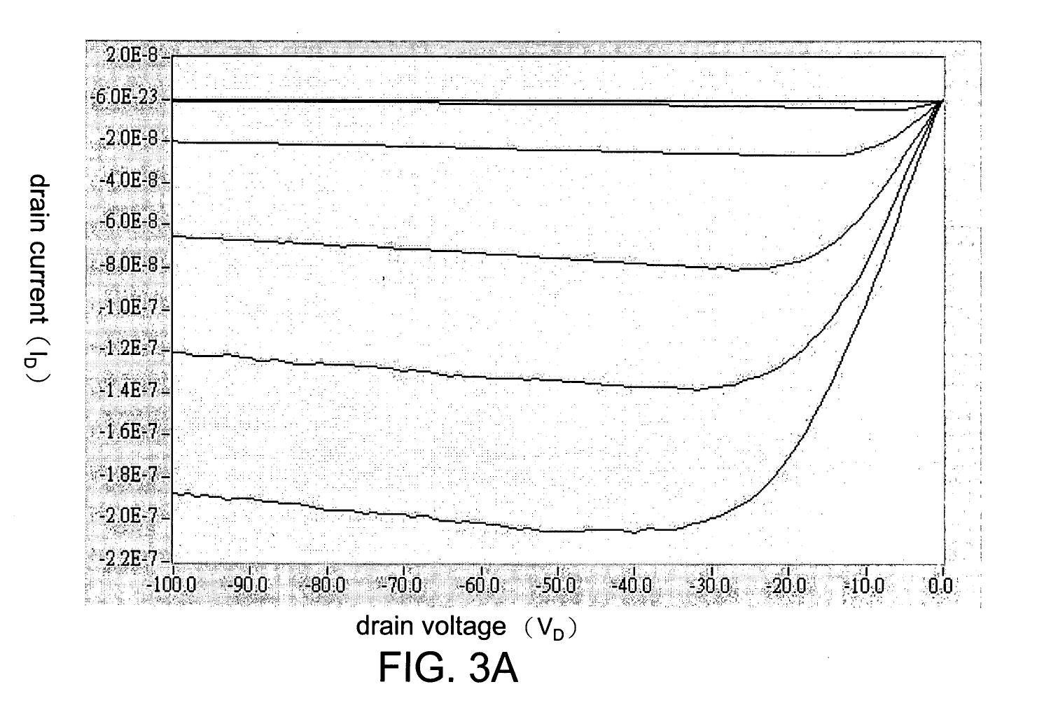

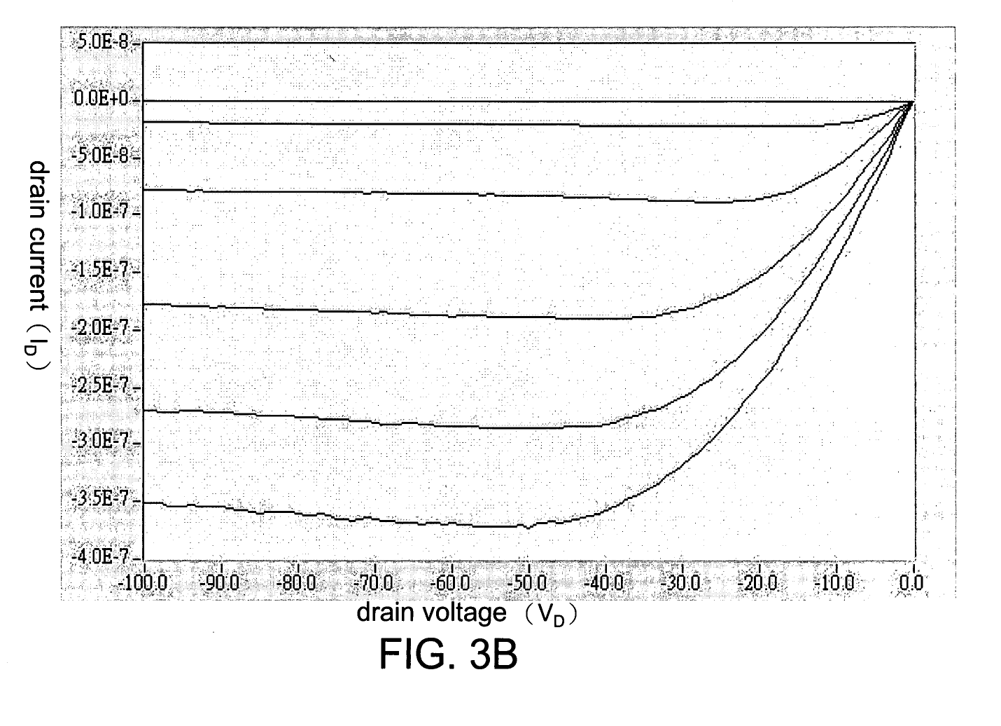

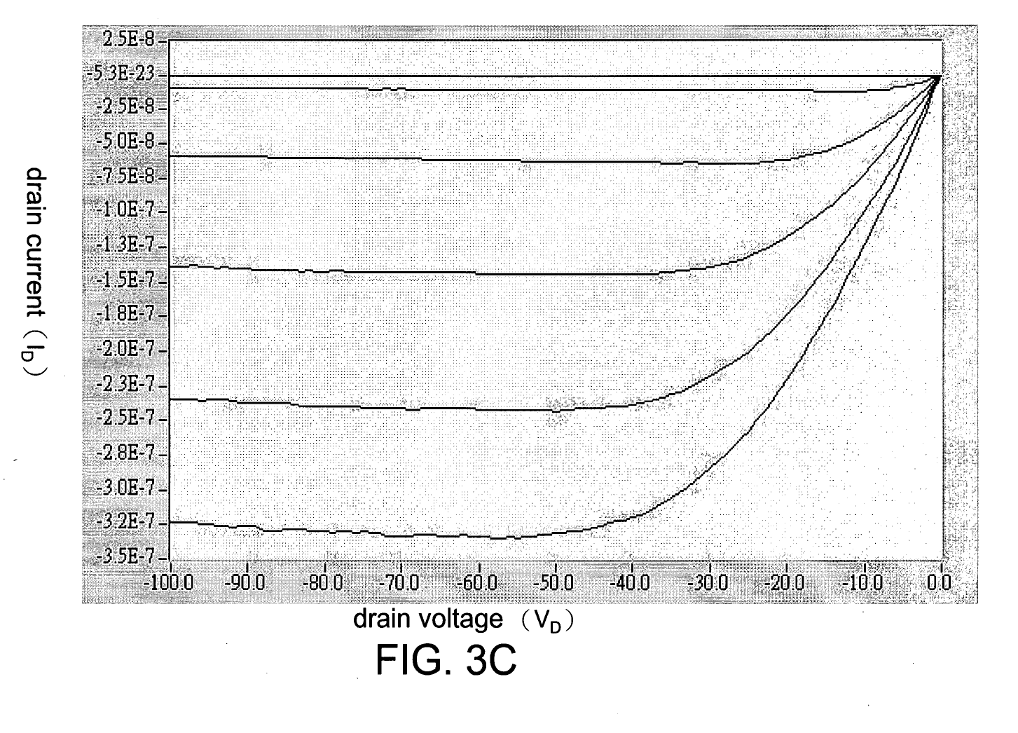

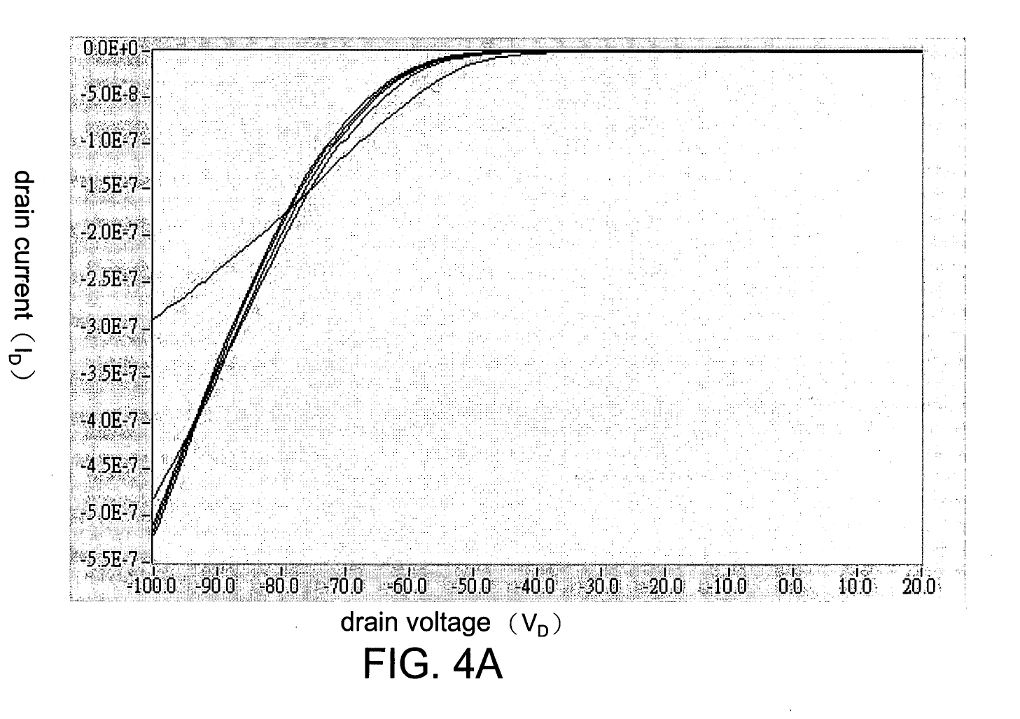

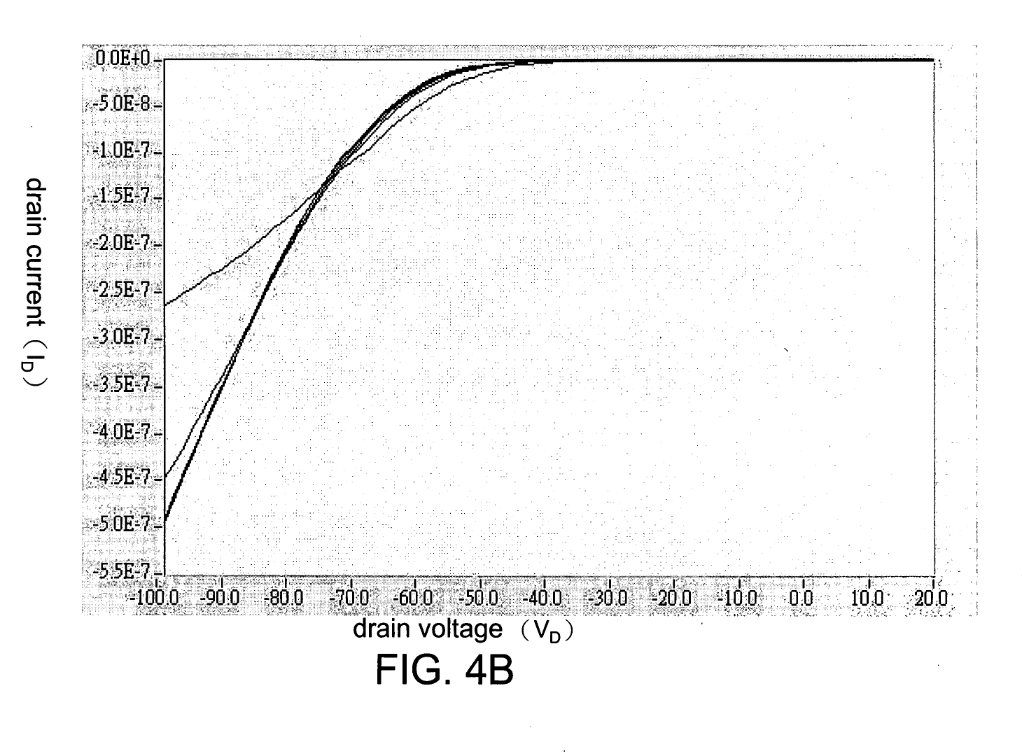

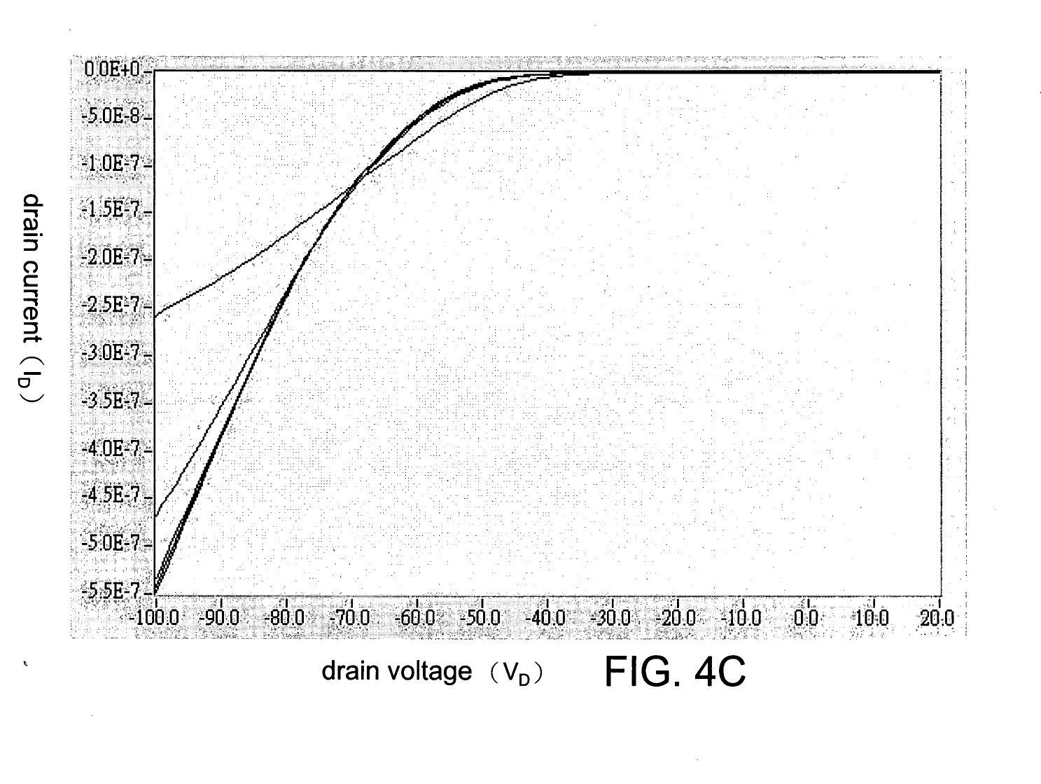

With simultaneous reference to FIGS. 3A to 3C and 4A to 4C, the electrical properties of the organic semiconductor device 40 in the disclosed embodiment are tested. In particular, FIGS. 3A to 3C show the I_{D}-V_{D} characteristic curves of the organic semiconductor device 40 after dropping twisted nematic liquid crystal (TNLC) droplets on the channel of the OTFT 10 that has gone through the above-mentioned process. The curve can be used to estimate the ON/OFF ratio, Ion/Ioff, under a fixed gate voltage. FIGS. 4A to 4C show the I_{D}-V_{G} characteristic curves of the organic semiconductor device 40 after dropping TNLC droplets on the channel of the OTFT 10 that has gone through the above-mentioned process. Using these diagrams, one can obtain the transconductance, gm=I_{D} (saturation)/V_{G}, between the drain current and the gate voltage under a fixed drain voltage. These results show that the I_{D}-V_{D} characteristic curves and the I_{D}-V_{G} characteristic curves do not differ too much, indicating that the electrical properties of the organic semiconductor device 40 do not deteriorate. Therefore, this method can be used to make TNLC display panel driven by the pentacene OTFT.

In this embodiment, the OTFT 10 is selected from the bottom contact, top contact, bottom gate, and top gate OTFT's. The materials of the first protective layer 20 and the second protective layer 30 are either organic or inorganic. The second protective layer 30 is made in a solution process, including spin coating, screen printing, inject printing, and spinless coating. The second protective layer 30 can also be formed using the same vapor phase deposition as the first protective layer 10, but with a different material. The vapor phase deposition can be chemical vapor deposition (CVD), organic vapor phase deposition (OVPD), co-evaporation, or other non-solution processes. Moreover, there may be several first protective layers 20 and several second protective layers 30, and the first protective layers 20 are organic and the second protective layers 30 are inorganic. They are deposited in an alternating way on the OTFT 10, forming a more uniform and protective layer.

The OTFT mentioned in this specification can be selected from the N-type metal oxide semiconductor field-effect transistor (NMOS TFT), P-type metal oxide semiconductor field-effect transistor (PMOS TFT), and complementary metal oxide semiconductor field-effect transistor (CMOS TFT). The above-mentioned embodiment uses a P-type organic semiconductor material, the pentacene OTFT. The following describes a second embodiment of the invention, which uses an OTFT made of an N-type organic semiconductor, copper hexadecafluorophthalocyanine (F16CuPc). In this embodiment, we use an OTFT with a channel length of 30 μm (step 100), measuring its electrical pre-values (I_{D}V_{D}). Afterwards, a parylene first protective layer is deposited to a thickness of 5000 Å (step 110). A 5% wt PVP solution is then used to perform spin coating, obtaining a thin film of about 6000 Å (step 120). This renders an organic semiconductor device with multiple protective layers.

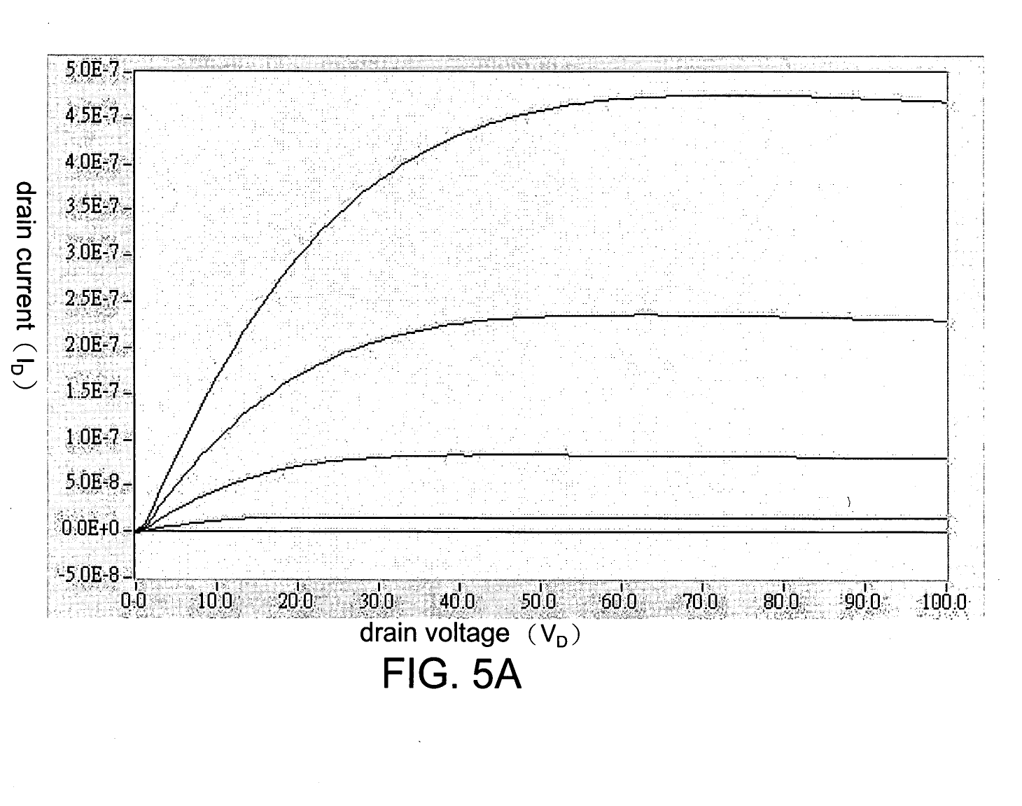

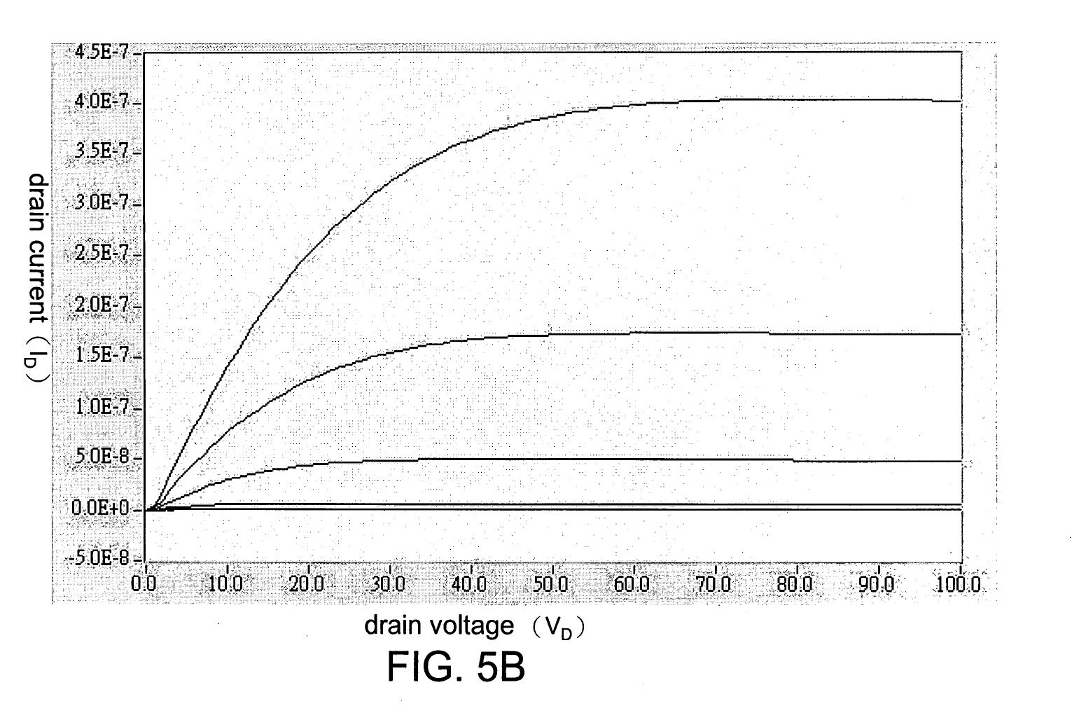

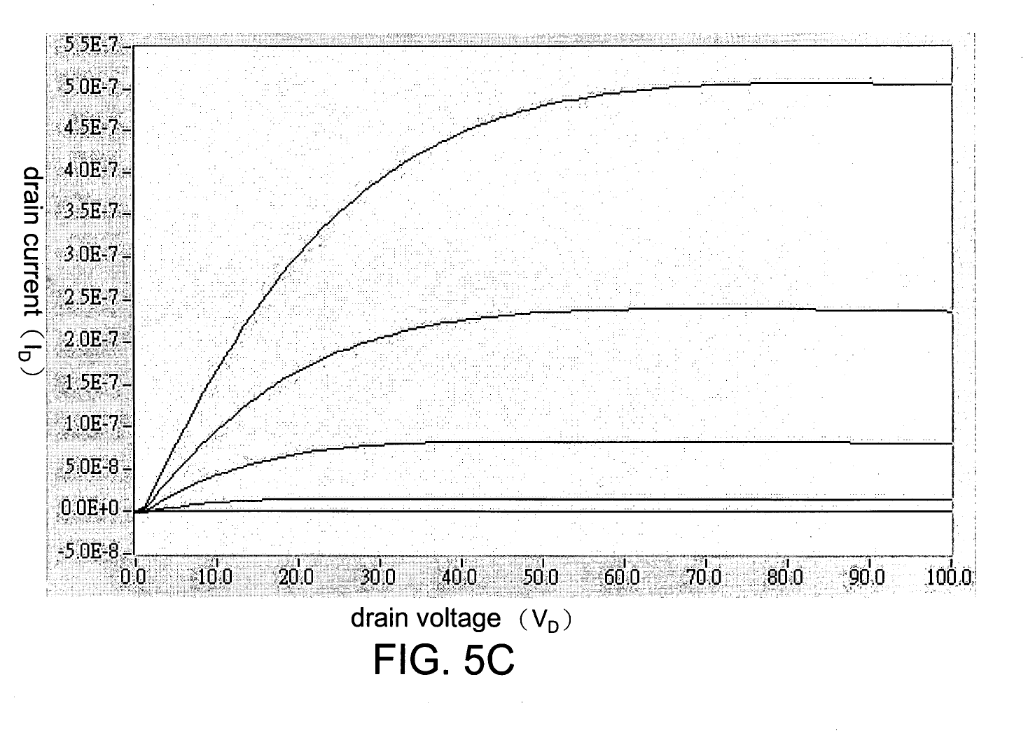

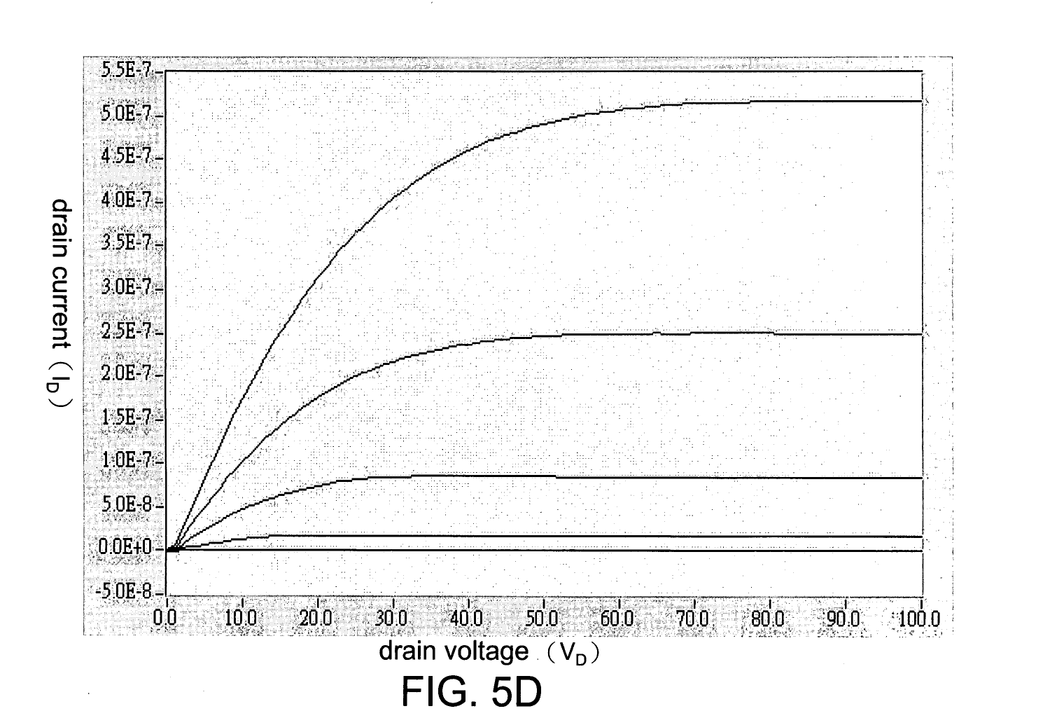

We measure the electrical properties of the OTFT after the manufacturing process. It is found that the electrical properties remain the original standard. The channel is dropped with TNLC. The electrical properties of the OTFT are found to be still normal. Disposed under the atmosphere for five days, the electrical properties of the OTFT are still the same as immediately after the TNLC droplets are deposited. The I_{D}-V_{D} characteristic curves are shown in FIGS. 5A to 5D. This shows that the multiple protective layers can be the F16CuPc protective layer of an N-type organic semiconductor material.

In summary, the disclosed organic semiconductor device and the method of making the same deposit the second protective layer by vapor phase deposition on the first protective layer to form multiple protective layers of the OTFT. Not only do the multiple protective layers have good uniformity, they can effectively protect the OTFT from the damage of liquid crystal. Moreover, the second protective layer is used for liquid crystal rubbing. Therefore, the organic semiconductor device with the protective layers has wider applications.

Certain variations would be apparent to those skilled in the art, which variations are considered within the spirit and scope of the claimed invention.

What is claimed is:

1. An organic semiconductor device with multiple protective layers, comprising:
an organic thin-film transistor (OTFT);
a first protective layer, deposited by vapor phase deposition on the OTFT; and
a second protective layer, deposited on the first protective layer.

2. The organic semiconductor device with multiple protective layers of claim 1, wherein the OTFT is selected from the group consisting of bottom contact, top contact, bottom gate, and top gate OTFT's.

3. The organic semiconductor device with multiple protective layers of claim 1, wherein the OTFT is selected from the group consisting of an N-type metal oxide semiconductor field effect transistor (NMOS FET), a P-type metal oxide semiconductor field effect transistor (PMOS FET) and a complementary metal oxide semiconductor field effect transistor (CMOS FET).

4. The organic semiconductor device with multiple protective layers of claim 1, wherein the second protective layer is formed in a solution process.

5. The organic semiconductor device with multiple protective layers of claim 4, wherein the solution process is selected from the group consisting of spin coating, screen printing, inject printing, and spinless coating.

6. The organic semiconductor device with multiple protective layers of claim 1, wherein the second protective layer is formed by vapor phase deposition.

7. The organic semiconductor device with multiple protective layers of claim 6, wherein the second protective layer and the first protective layer are made of different materials.

8. The organic semiconductor device with multiple protective layers of claim 1, wherein the first protective layer is an inorganic material.

9. The organic semiconductor device with multiple protective layers of claim 1, wherein the first protective layer is an organic material.

10. The organic semiconductor device with multiple protective layers of claim 9, wherein the organic material is selected from the group consisting of parylene-N, parylene-C, and parylene-D.

11. The organic semiconductor device with multiple protective layers of claim 9, wherein the second protective layer is made of an inorganic material.

12. The organic semiconductor device with multiple protective layers of claim 11, wherein there are a plurality of the first protective layers and the second protective layers stacked in an alternating way.

13. The organic semiconductor device with multiple protective layers of claim 1, wherein the vapor phase deposition is selected from the group consisting of chemical vapor deposition (CVD), organic vapor phase deposition (OVPD), and co-evaporation.

14. The organic semiconductor device with multiple protective layers of claim 1, wherein the second protective layer is poly vinyl phenol (PVP).

15. The organic semiconductor device with multiple protective layers of claim 1, wherein the second protective layer is an organic material.

16. A method of making an organic semiconductor device with multiple protective layers, comprising the steps of:
providing an OTFT;
forming a first protective layer on the OTFT by vapor phase deposition; and
forming a second protective layer on the first protective layer.

17. The method of claim 16, wherein the OTFT is selected from the group consisting of bottom contact, top contact, bottom gate, and top gate OTFT's.

18. The method of claim 16, wherein the OTFT is selected from the group consisting of an N-type metal oxide semiconductor field effect transistor (NMOS FET), a P-type metal oxide semiconductor field effect transistor (PMOS FET) and a complementary metal oxide semiconductor field effect transistor (CMOS FET).

19. The method of claim 16, wherein the step of forming a second protective layer utilizes a solution process.

20. The method of claim 19, wherein the solution process is selected from the group consisting of spin coating, screen printing, inkjet printing, and spinless coating.

21. The method of claim 16, wherein the step of forming a second protective layer utilizes vapor phase deposition.

22. The method of claim 16, wherein the second protective layer and the first protective layer are made of different materials.

23. The method of claim 16, wherein the first protective layer is an inorganic material.

24. The method of claim 16, wherein the first protective layer is an organic material.

25. The method of claim 24, wherein the organic material is selected from the group consisting of parylene-N, parylene-C, and parylene-D.

26. The method of claim 24, wherein the second protective layer is made of an inorganic material.

27. The method of claim 26, wherein there are a plurality of the first protective layers and the second protective layers stacked in an alternating way.

28. The method of claim 16, wherein the vapor phase deposition is selected from the group consisting of chemical vapor deposition (CVD), organic vapor phase deposition (OVPD), and co-evaporation.

29. The method of claim 16, wherein the second protective layer is poly vinyl phenol (PVP).

30. The method of claim 16, wherein the second protective layer is an organic material.
